(19) United States
(12) Patent Application Publication
(10) Pub. No.: US 2022/0229946 A1
(43) Pub. Date: Jul. 21, 2022

(54) Systems and Methods for Roof Area and Slope Estimation Using a Point Set

(71) Applicant: Insurance Services Office, Inc., Jersey City, NJ (US)

(72) Inventors: Ryan Mark Justus, Lehi, UT (US); Antonio Godino Cobo, South Jordan, UT (US); Bryce Zachary Porter, Lehi, UT (US)

(73) Assignee: Insurance Services Office, Inc., Jersey City, NJ (US)

(21) Appl. No.: 17/580,279

(22) Filed: Jan. 20, 2022

Related U.S. Application Data
(60) Provisional application No. 63/139,477, filed on Jan. 20, 2021.

(51) Int. Cl. G06F 30/13

(52) U.S. Cl. CPC G06F 30/13

(57) ABSTRACT

Systems and methods for roof area and slope estimation using a point set are provided. The system selects roof structure points having a high probability of being positioned on a top surface of a structure present in the region of interest point set. Then, the system determines a footprint of the structure associated with the selected roof structure points. The system determines a distribution of the slopes of the roof structure points and generates a slope distribution report indicative of prominent slopes of the roof structure and each slope's contribution toward (percentage composition of) the total roof structure. The system then determines an area of the roof structure based on the footprint of the structure and the slope distribution report.

### RELATED APPLICATIONS

This application claims priority to U.S. Provisional Patent Application Ser. No. 63/139,477 filed on Jan. 20, 2021, the entire disclosure of which is hereby expressly incorporated by reference.

### BACKGROUND

### Technical Field

The present disclosure relates generally to the field of computer modeling of structures. More particularly, the present disclosure relates to systems and methods for roof area and slope estimation using a point set.

### Related Art

Accurate and rapid identification and depiction of objects from digital images (e.g., aerial images, satellite images, etc.) is increasingly important for a variety of applications. For example, information related to various features of buildings, such as roofs, walls, doors, etc., is often used by construction professionals to specify materials and associated costs for both newly-constructed buildings, as well as for replacing and upgrading existing structures. Further, in the insurance industry, accurate information about structures may be used to determine the proper costs for insuring buildings/structures. For example, a surface area and slope of a roof structure corresponding to a building/structure are valuable data points.

Various software systems have been implemented to process ground images, aerial images and/or overlapping image content of an aerial image pair to generate a three-dimensional (3D) model of a building present in the images and/or a 3D model of the structures thereof (e.g., a roof structure). However, these systems can be computationally expensive and have drawbacks, such as missing camera parameter set information associated with each ground and/or aerial image and an inability to provide a higher resolution estimate of a position of each aerial image (where the aerial images overlap) to provide a smooth transition for display or computation and human error. Moreover, such systems often require manual modeling by humans in order to generate accurate models of structures (e.g., by manually reconstructing surfaces of the building). As such, the ability to determine a surface area and slope of a roof structure, as well as generate a report of a slope distribution of the roof structure and measurements thereof without first performing a surface reconstruction of the roof structure is a powerful tool.

Thus, what would be desirable is a system that automatically and efficiently determines a surface area and slope of a roof structure and generates a report of a slope distribution of the roof structure and measurements thereof from a point set without requiring creation of a surface reconstruction of the roof structure. Accordingly, the systems and methods disclosed herein solve these and other needs.

### SUMMARY

This present disclosure relates to systems and methods for roof area and slope estimation using a point set. The system selects roof structure points from a point set of a region of interest. In particular, the system selects roof structure points having a high probability of being positioned on a top surface of a structure present in the region of interest point set. Then, the system determines a footprint of the structure associated with the selected roof structure points. The system determines a distribution of the slopes of the roof structure points and generates a slope distribution report indicative of prominent slopes of the roof structure and each slope's contribution toward (percentage composition of) the total roof structure. The system then determines an area of the roof structure based on the footprint of the structure and the slope distribution report.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating an embodiment of the system of the present disclosure;

FIG. 2 is a diagram illustrating a point set of a region of interest having a structure and corresponding roof structure present therein;

FIG. 3 is a flowchart illustrating overall processing steps carried out by the system of the present disclosure;

FIG. 4 is a flowchart illustrating step 52 of FIG. 3 in greater detail;

FIG. 5 is a diagram illustrating a point set of the roof structure of FIG. 2;

FIG. 6 is a flowchart illustrating step 54 of FIG. 3 in greater detail;

FIG. 7 is a diagram illustrating a footprint of the structure corresponding to the roof structure of FIG. 5;

FIG. 8 is a flowchart illustrating step 56 of FIG. 3 in greater detail;

FIG. 9 is a diagram illustrating a histogram corresponding to the roof structure of FIG. 5;

FIG. 10 is a flowchart illustrating step 58 of FIG. 3 in greater detail;

FIG. 11 is a table illustrating a slope distribution report;

FIG. 12 is a flowchart illustrating step 60 of FIG. 3 in greater detail;

FIG. 13 is a diagram illustrating a slope correction factor; and

FIG. 14 is a diagram illustrating another embodiment of the system of the present disclosure.

### DETAILED DESCRIPTION

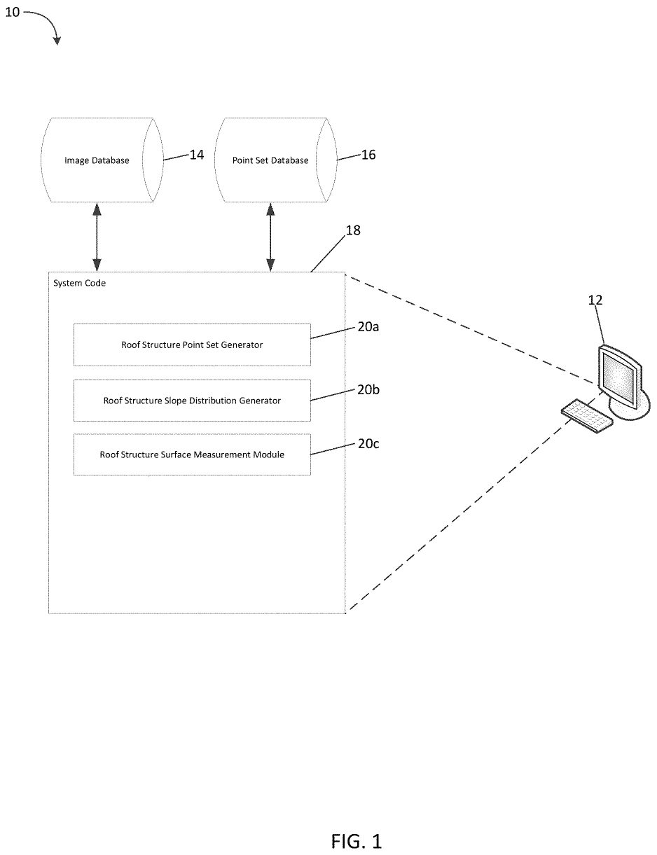

The present disclosure relates to systems and methods for roof area and slope estimation using a point set, as described in detail below in connection with FIGS. 1-14.

Turning to the drawings, FIG. 1 is a diagram illustrating an embodiment of the system 10 of the present disclosure. The system 10 could be embodied as a central processing unit 12 (processor) in communication with an image database 14 and/or a point set database 16. The processor 12 could include, but is not limited to, a computer system, a server, a personal computer, a cloud computing device, a smart phone, or any other suitable device programmed to carry out the processes disclosed. The system 10 could generate at least one point set of a structure based on a structure present in at least one image obtained from the image database 14. Alternatively, as discussed below, the system 10 could retrieve at least one stored point set of a structure from the point set database 16.

The image database 14 could include digital images and/or digital image datasets comprising ground images, aerial images, satellite images, etc. Further, the datasets could include, but are not limited to, images of residential and commercial buildings. The database 16 could store one or more three-dimensional representations of an imaged location (including structures at the location), such as point clouds, LiDAR files, etc., and the system could operate with such three-dimensional representations. As such, by the terms “image” and “imagery” as used herein, it is meant not only optical imagery (including aerial and satellite imagery), but also three-dimensional imagery and computer-generated imagery, including, but not limited to, LiDAR, point clouds, three-dimensional images, etc.

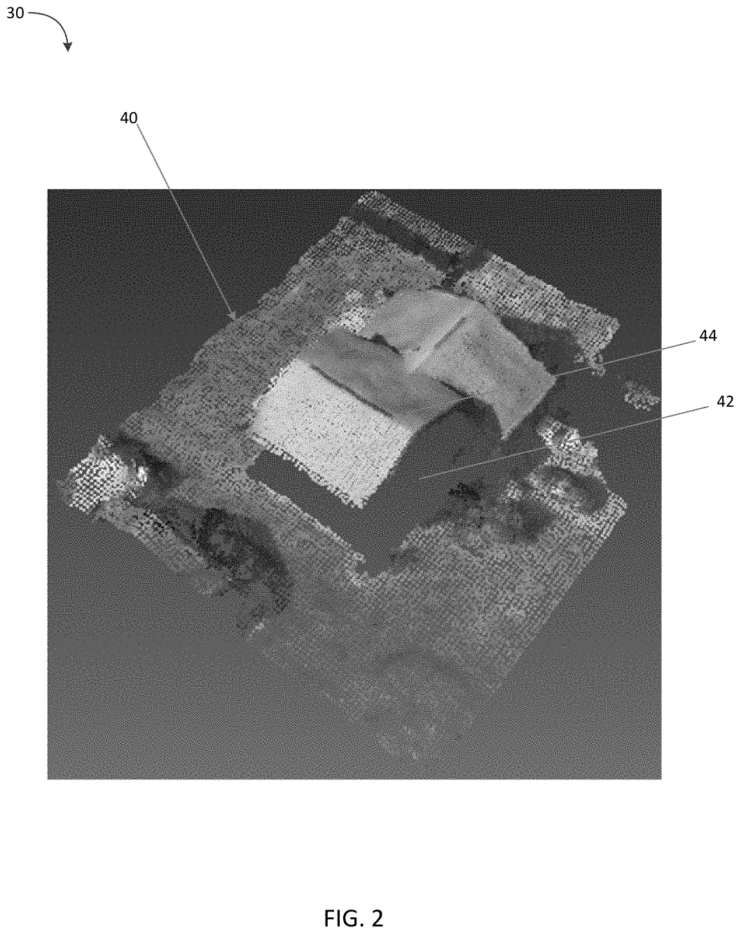

The processor 12 executes system code 18 which estimates an area and a slope of a roof structure based on a point set of a region of interest received from the point set database 16 having a structure and corresponding roof structure present therein. For example, illustrated in FIG. 2 is a diagram 30 illustrating a region of interest point set 40 having a structure 42 and corresponding roof structure 44 present therein.

Referring back to FIG. 1, the system 10 includes system code 18 (i.e., non-transitory, computer-readable instructions) stored on a computer-readable medium and executable by the hardware processor 12 or one or more computer systems. The code 18 could include various custom-written software modules that carry out the steps/processes discussed herein, and could include, but is not limited to, a roof structure point set generator 20a, a roof structure slope distribution generator 20b, and a roof structure surface measurement module 20c. The code 18 could be programmed using any suitable programming languages including, but not limited to, C, C++, C #, Java, Python or any other suitable language. Additionally, the code 18 could be distributed across multiple computer systems in communication with each other over a communications network, and/or stored and executed on a cloud computing platform and remotely accessed by a computer system in communication with the cloud platform. The code 18 could communicate with the image database 14 and/or the point set database 16, which could be stored on the same computer system as the code 18, or on one or more other computer systems in communication with the code 18.

Still further, the system 10 could be embodied as a customized hardware component such as a field-programmable gate array (“FPGA”), application-specific integrated circuit (“ASIC”), embedded system, or other customized hardware components without departing from the spirit or scope of the present disclosure. It should be understood that FIG. 1 is only one potential configuration, and the system 10 of the present disclosure can be implemented using a number of different configurations.

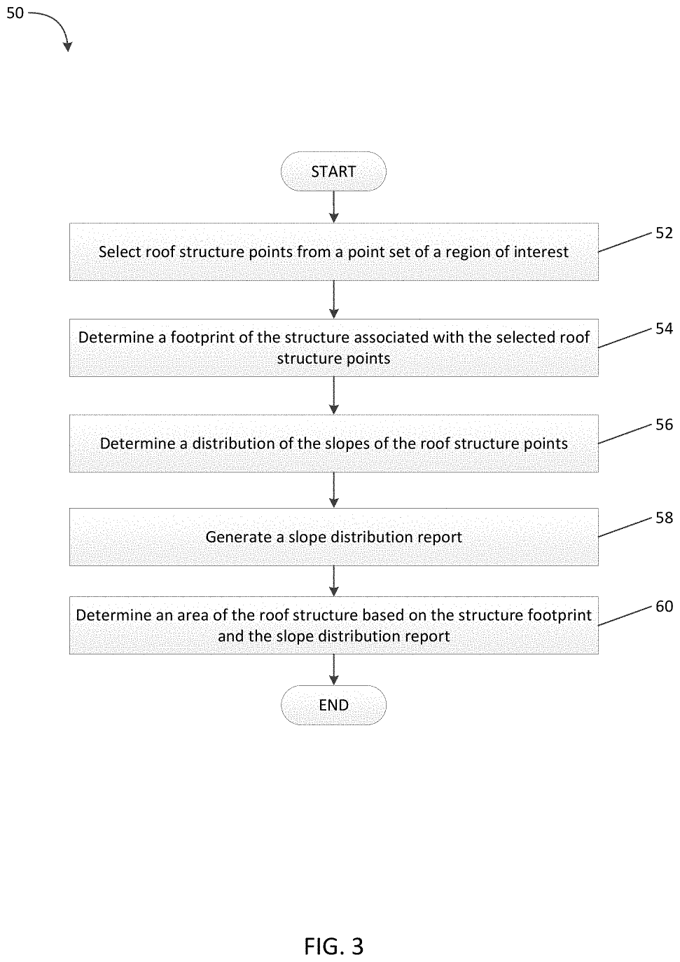

FIG. 3 is a flowchart illustrating overall processing steps 50 carried out by the system 10 of the present disclosure. Beginning in step 52, the system 10 selects roof structure points from a point set of a region of interest. In particular, the system 10 selects roof structure points having a high probability of being positioned on a top surface of a structure present in the region of interest point set. In step 54, the system 10 determines a footprint of the structure associated with the selected roof structure points. Then, in step 56, the system 10 determines a distribution of the slopes of the roof structure points. In step 58, the system 10 generates a slope distribution report indicative of prominent slopes of the roof structure and their respective contributions toward (percentages of composition of) the total roof structure. Lastly, in step 60, the system 10 determines an area of the roof structure based on the footprint of the structure and the slope distribution report.

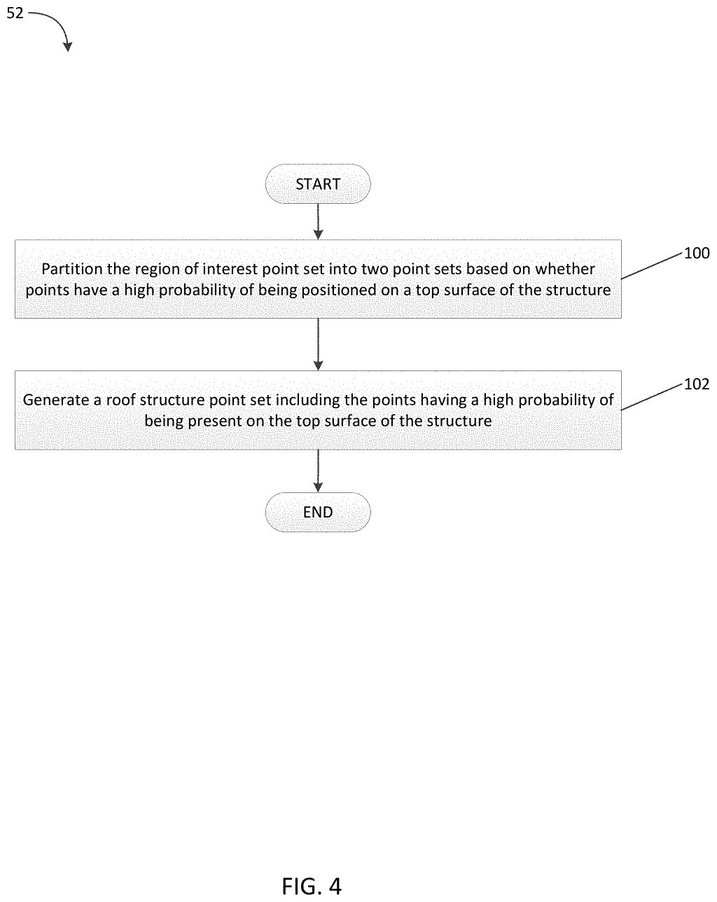

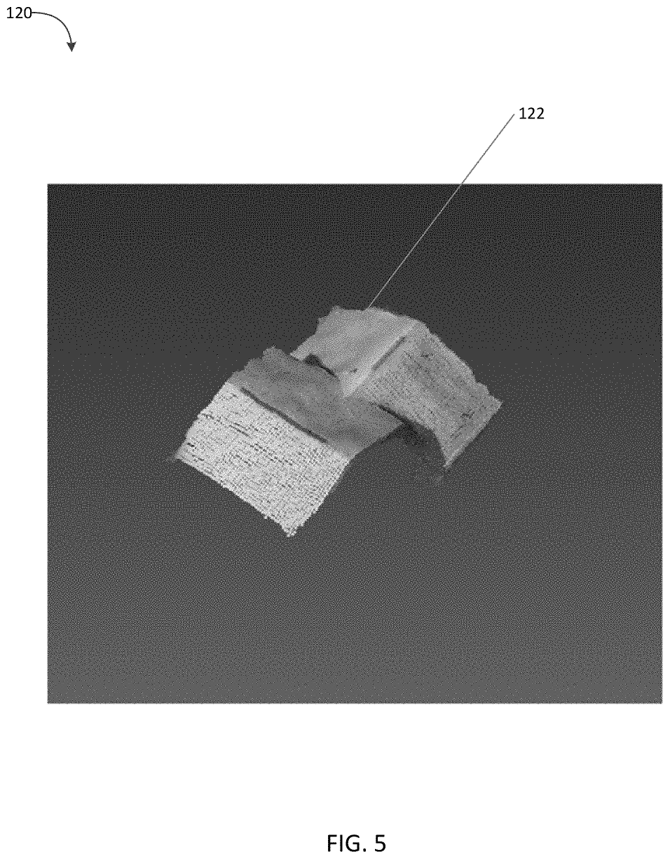

FIG. 4 is a flowchart illustrating step 52 of FIG. 3 in greater detail. Beginning in step 100, the system 10 partitions the region of interest point set 40 into two point sets based on whether points have a high probability of being positioned on a top surface of the structure 42. It should be understood that points having a high probability of being positioned on the top surface of the structure 42 can be selected by any method that yields a set of three-dimensional (3D) points spanning the roof structure 44 of the structure 42. For example, the points can be selected by utilizing a footprint of the structure 42 in the XY-plane, via a neural network that classifies points as being part of the roof structure 44, via a 3D convolutional neural network that processes the points and outputs a voxel representation of the roof structure 44 with the resulting roof structure points being a characteristic point of the voxel, or via a projection onto an image having labeled pixels indicative of the roof structure 44. In step 102, the system 10 generates a roof structure point set including the selected points having a high probability of being present on the top surface of the structure 42. In particular, outlier points (e.g., points that do not have a high probability of being positioned on the top surface of the structure 42) can be removed based on properties thereof including, but not limited to, point density around a respective point, a non-planar region, or an outlier removal algorithm utilizing prior constraints associated with common roof structure configurations. For illustration, FIG. 5 shows a diagram 120 illustrating a roof structure point set 122 corresponding to the roof structure 44 of the structure 42 of FIG. 2, generated by the system.

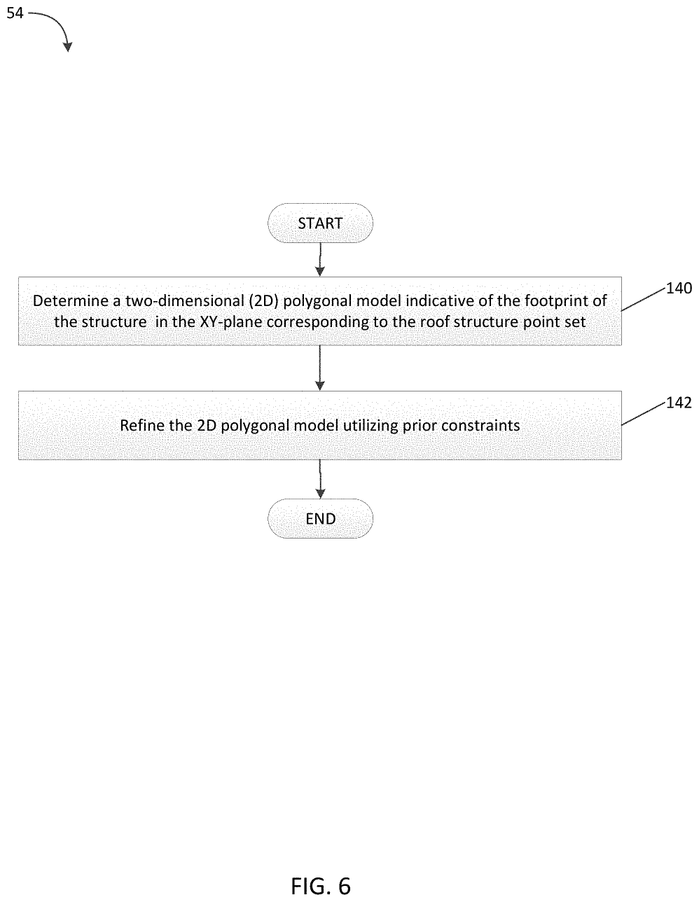

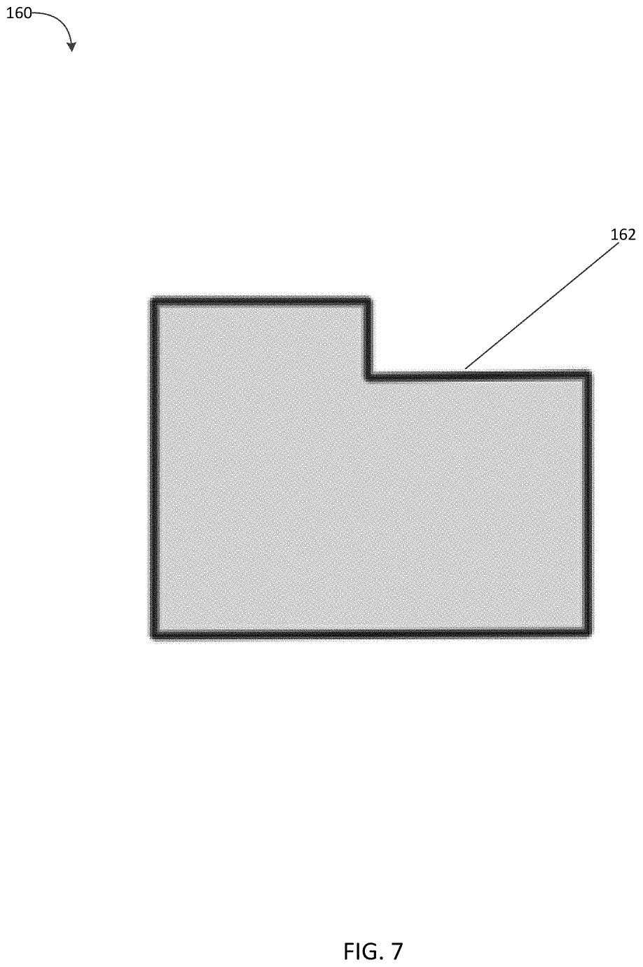

FIG. 6 is a flowchart illustrating step 54 of FIG. 3 in greater detail. In step 140, the system 10 determines a two-dimensional (2D) polygonal model indicative of a footprint of the structure 42 in the XY-plane corresponding to the roof structure point set 122. It should be understood that the 2D polygonal model can be determined by any suitable method. For example, the system 10 can determine the 2D polygonal model by determining a concave hull approximation of the roof structure point set 122 via an alpha shape algorithm or by a neural network that processes the roof structure point set 122 to generate a 2D grid indicative of the footprint of the structure 42. Alternatively, the system 10 may utilize an existing footprint of the structure 42 if the existing footprint meets minimum quality thresholds. In step 142, the system 10 can refine the 2D polygonal model utilizing prior constraints including, but not limited to, angles, symmetry and simplicity. For illustration, FIG. 7 shows a diagram 160 illustrating a footprint 162 of the structure 42 corresponding to the roof structure point set 122 of FIG. 5, generated by the system.

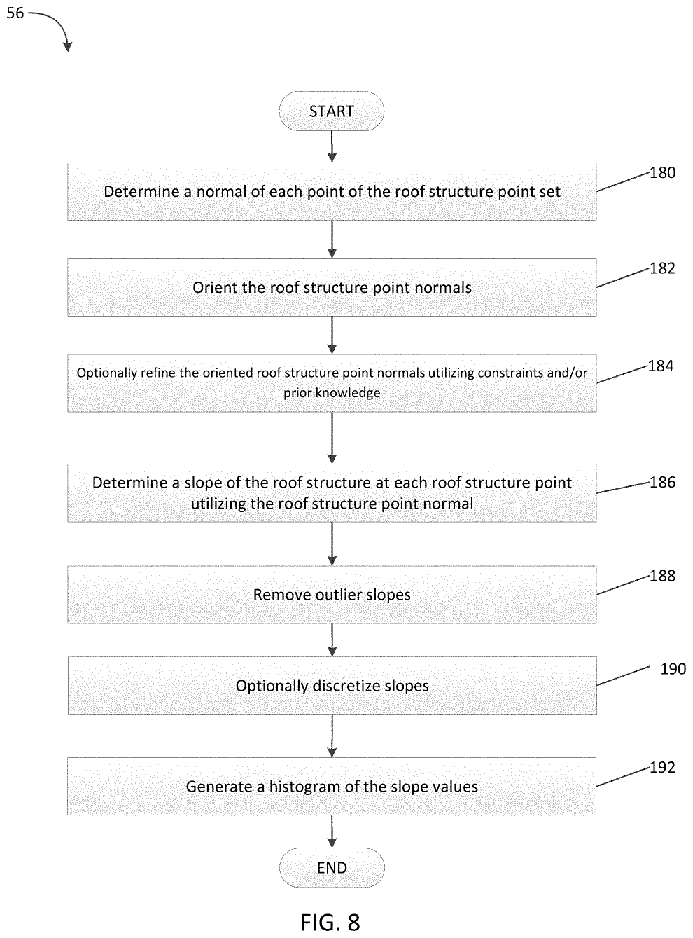

FIG. 8 is a flowchart illustrating step 56 of FIG. 3 in greater detail. In step 180, the system 10 determines a normal of each 3D point of the roof structure point set 122. It should be understood that the normal of each point can be determined by any suitable method. For example, the system 10 can determine the normal of each point by utilizing a neural network (e.g., Pointnet) which receives each point, in addition to optional features thereof (e.g., color), and computes a normal for each point or by selecting a set of points in a region encompassing each point and determining a plane of the region via principle component analysis, singular value decomposition, Random Sample Consensus (RANSAC) or a similar plane estimation algorithm.

In step 182, the system 10 orients each roof structure point normal such that the z-component is a positive number. In step 184, the system 10 optionally refines the oriented roof structure point normals based on constraints and/or prior knowledge of a roof structure including, but not limited to, a probable orientation of the roof structure, symmetry constraints, and any other prior knowledge of the roof structure. In step 186, the system 10 determines a slope of the roof structure at each roof structure point utilizing the oriented normal thereof. Then, in step 188, the system 10 removes outlier slopes determined to lie outside of a reasonable range of slopes of the roof structure.

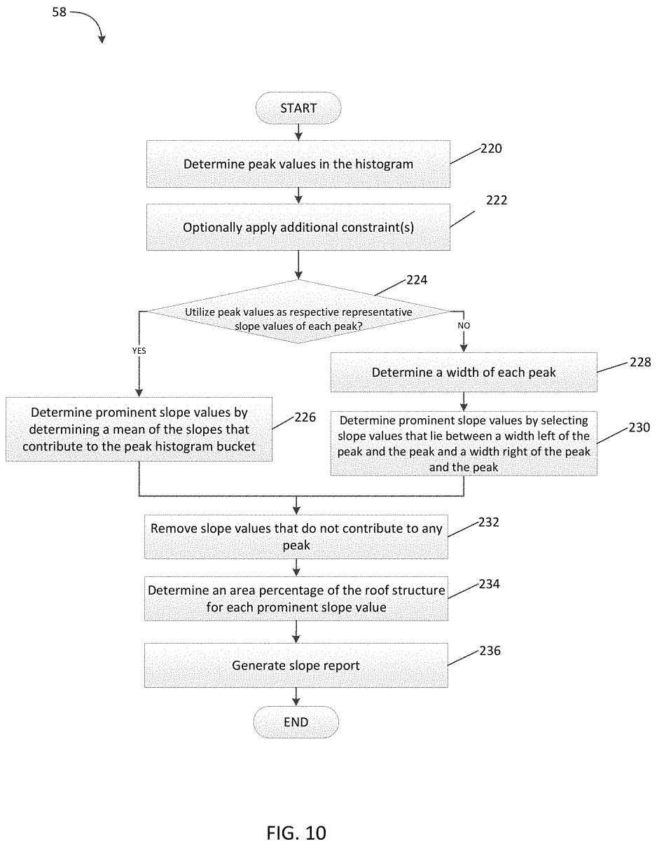

In step 190, the system optionally discretizes the slopes according to a selected resolution. Lastly, in step 192, the system 10 generates a histogram of the slope values. As discussed below in reference to FIG. 10, it should be understood that a constant multiplier and/or bias may be applied to the slope values based on constraints.

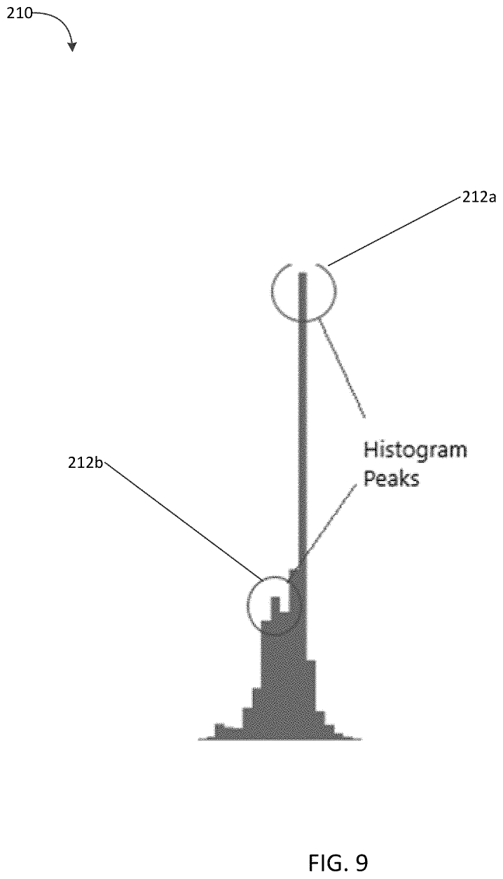

FIG. 9 is a diagram 210 illustrating a histogram corresponding to the roof structure point set 122 of FIG. 5. As shown in FIG. 9, peaks 212a and 212b are indicative of peak values of the histogram. The system processes the histograms of the structure point sets 122 as discussed in greater detail below in connection with FIG. 10. The histogram values indicate the estimated surface slopes (vertical rise over horizontal run) represented in the point cloud at a particular point.

FIG. 10 is a flowchart illustrating step 58 of FIG. 3 in greater detail. In step 220, the system 10 determines peaks of the histogram. In step 222, the system 10 optionally applies at least one additional constraint to the peaks including, but not limited to, minimum peak prominence, peak spacing, or any constraint with respect to a probable roof slope distribution. As mentioned above, peaks are indicative of peak values of the histogram. In step 224, the system 10 determines whether to utilize the peak values as respective representative slope values of each peak. If the system 10 utilizes the peak values as the respective representative slope values of each peak, then the process proceeds to step 226. In step 226, the system 10 determines prominent slope values by determining a mean of the slopes that contribute to the peak histogram bucket. Alternatively, if the system 10 does not utilize the peak values as the respective representative slope values of each peak, then the process proceeds to step 228. In step 228, the system 10 determines a width of each peak. For example, the system 10 determines a width left of a peak and a width right of the peak independently based on at least one of a prominence of adjacent peaks, a peak height threshold and a minimum number of samples. Then, in step 230, the system 10 determines the prominent slope values by selecting slope values that lie between (a) the width left of the peak and the peak and (b) the width right of the peak and the peak.

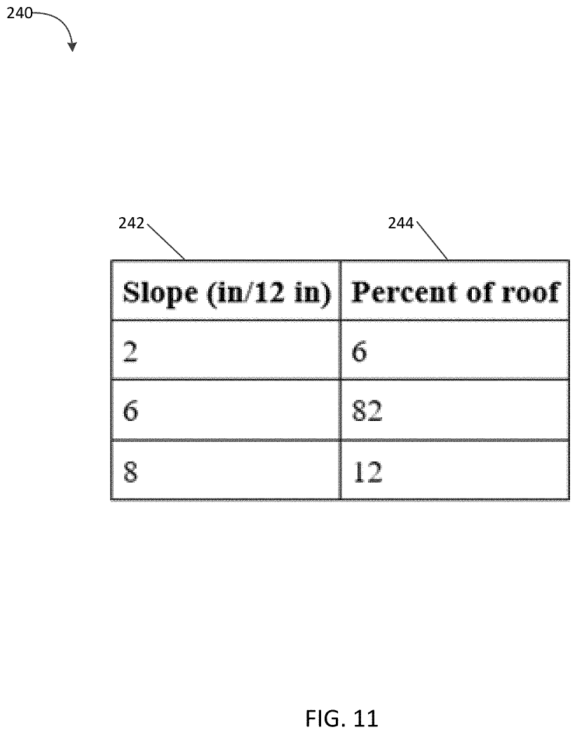

In step 232, the system 10 removes the slope values that do not contribute to any peak. Slope values that do not contribute to any peak are indicative of noise and are therefore removed. Then, in step 234, the system 10 determines an area percentage of the roof structure for each prominent slope value. In particular, the system 10 determines a total number of slope values that contribute to each prominent slope value and divides a point count for each prominent slope value by the total number of slope values that contribute to each prominent slope value. It should be understood that the system 10 can optionally round prominent slope values to whole integers based on a common standard unit of measurement (e.g., inches per foot). In step 236, the system 10 generates a slope distribution report. The slope distribution report can be represented as a table which maps prominent slope values to respective area percentages of a roof structure. For example, FIG. 11 is a table 240 illustrating a slope distribution report having prominent slope values 242 and corresponding area percentages of a roof structure 244.

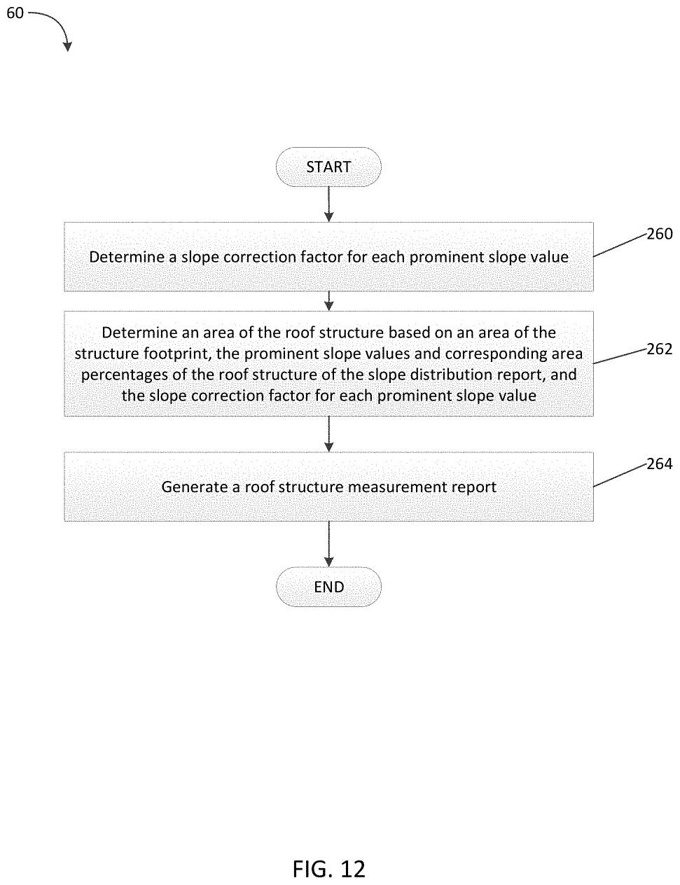

FIG. 12 is a flowchart illustrating step 60 of FIG. 3 in greater detail. In step 260, the system determines a slope correction factor for each prominent slope value. In particular, the slope correction factor is given by Equation 1 as follows:

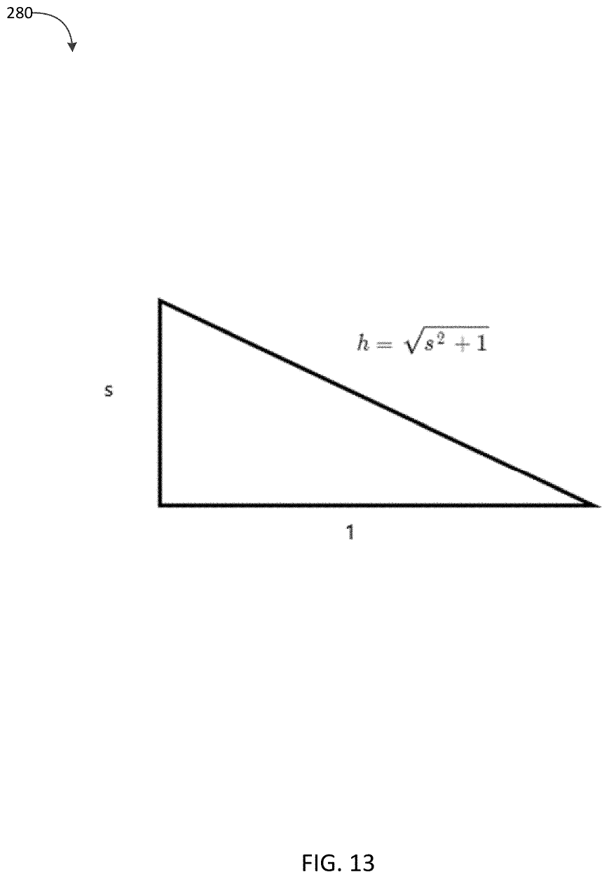

h=\sqrt{s²+1} Equation 1

where s denotes the slope and is measured as a rise in elevation in the z direction per unit run in the XY-plane. In this regard, FIG. 13 is a diagram 280 illustrating the slope correction factor as a hypotenuse of a triangle with slope s as a base and 1 as a complement base. Referring back to FIG. 12, in step 262, the system 10 determines an area of the roof structure based on an area of the structure footprint, the prominent slope values and corresponding area percentages of the roof structure from the slope distribution report, and the slope correction factor for each prominent slope value. In particular, the area of the roof structure is given by Equation 2 as follows:

$$A = {\sum }_{i}^{N} ( a * {p}_{i} * {h}_{i} ) \qquad Equation 2$$

where A denotes an area of the roof structure, a denotes an area of the structure footprint, pᵢ denotes an area percentage of the roof structure at an ith slope value in the distribution slope report and hᵢ denotes a slope correction factor at the ith slope value in the distribution slope report.

Alternatively, the system 10 may utilize the entire point slope distribution to determine an area of the roof structure given by Equation 3 as follows:

$$A = \frac{a}{N} * {\sum }_{i}^{N} ( {h}_{i} ) \qquad Equation 3$$

where A denotes an area of the roof structure, a denotes an area of the structure footprint, N denotes a number of roof structure points and hᵢ denotes a slope correction factor at the ith point.

In step 264, the system 10 generates a roof structure measurement report that includes, but is not limited to, the slopes and area of the roof structure determined from the roof structure point set 122. It should be understood that additional measurements with respect to the roof structure may be included in the roof structure measurement report including, but not limited to, roof heights, eave heights, ridge heights, valley lengths, hip ridge lengths, ridge lengths, or any other relevant roof structure measurement.

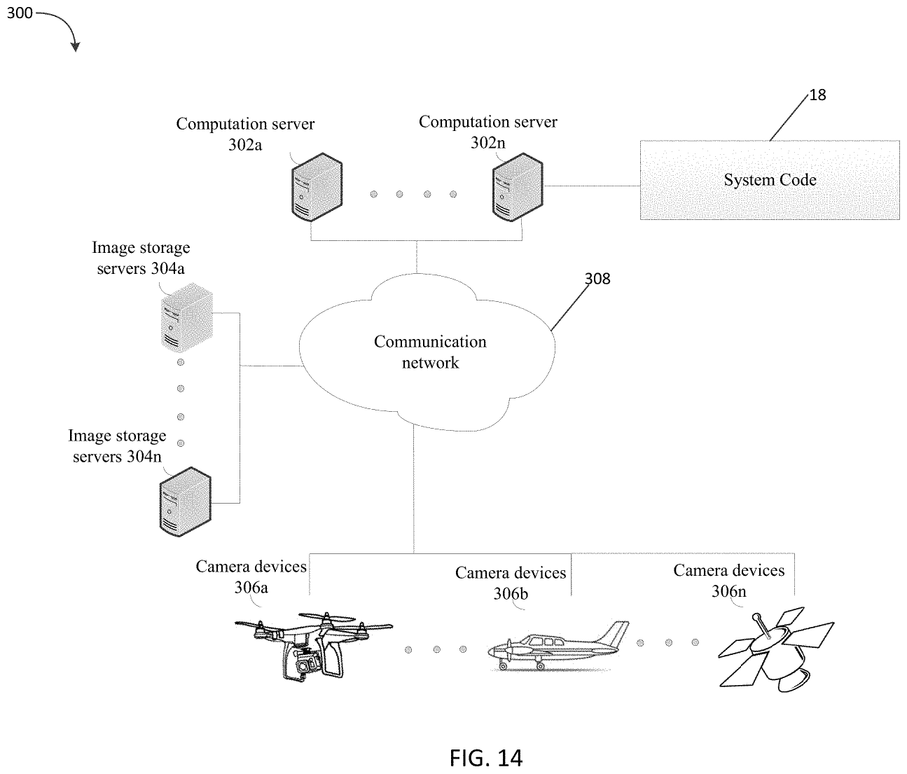

FIG. 14 a diagram illustrating another embodiment of the system 300 of the present disclosure. In particular, FIG. 14 illustrates additional computer hardware and network components on which the system 300 could be implemented. The system 300 can include a plurality of computation servers 302a-302n having at least one processor and memory for executing the computer instructions and methods described above (which could be embodied as system code 18). The system 300 can also include a plurality of image storage servers 304a-304n for receiving image data and/or video data. The system 300 can also include a plurality of camera devices 306a-306n for capturing image data and/or video data. For example, the camera devices can include, but are not limited to, an unmanned aerial vehicle 306a, an airplane 306b, and a satellite 306n. The internal servers 302a-302n, the image storage servers 304a-304n, and the camera devices 306a-306n can communicate over a communication network 308. Of course, the system 300 need not be implemented on multiple devices, and indeed, the system 300 could be implemented on a single computer system (e.g., a personal computer, server, mobile computer, smart phone, etc.) without departing from the spirit or scope of the present disclosure.

Having thus described the system and method in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure.

What is claimed is:

1. A system for estimating at least one attribute of a structure, comprising:
a memory storing a point set; and
a process in communication with the memory, the processor performing the steps of:
receiving the point set from the memory;
selecting a plurality of roof structure points from said point set having a high probability of being positioned on a top surface of a structure;
determining a footprint of the structure associated with the plurality of roof structure points; and
determining at least one attribute of the structure based on the plurality of roof structure points.

2. The system of claim 1, wherein the at least one attribute comprises a slope of the structure.

3. The system of claim 2, wherein the processor determines a distribution of slopes of the roof structure points and generates a slope distribution report indicative of prominent slopes of the roof structure.

4. The system of claim 3, wherein the slope distribution report indicates a contribution by each slope toward the total roof structure.

5. The system of claim 3, wherein the processor determines an area of the structure based on the footprint of the structure and the slope distribution report.

6. The system of claim 1, wherein the processor selects the plurality of roof structure points by partitioning a region of interest into two point sets based on whether the points have a high probability of being positioned on the top surface of the structure.

7. The system of claim 1, wherein the processor determines the footprint of the structure by determining a two-dimensional (2D) polygonal model indicative of the footprint of the structure in an XY plane corresponding to the point set.

8. The system of claim 1, wherein the processor refines the 2D polygonal model using at least one prior constraint.

9. The system of claim 3, wherein the processor determines the distributions of slopes of the roof structure points by:
determining a normal of each point of the roof structure point set;
orienting each normal for each point of the roof structure point set;
determining a slope of the structure at each roof structure point set utilizing each normal for each point of the roof structure point set;
removing outlier slopes; and
generating a histogram of slope values.

10. The system of claim 9, further comprising refining each normal for each point of the roof structure points utilizing a constraint or prior knowledge.

11. The system of claim 9, further comprising discretizing each slope.

12. The system of claim 9, further comprising determining peak values in the histogram and determining whether to utilize the peak values as respective representative slope values of each peak.

13. The system of claim 12, further comprising applying constraints to the histogram.

14. The system of claim 12, further comprising determining prominent slope values by determining a mean of the slopes that contributes to a peak histogram bucket.

15. The system of claim 12, further comprising determining a width of each peak value.

16. The system of claim 15, further comprising determining prominent slope values by selecting slope values that lie between a width left of a peak and the peak and between a width right of the peak and the peak.

17. The system of claim 12, further comprising removing slope values that do not contribute to any peak.

18. The system of claim 17, further comprising determining an area percentage of the roof structure for each prominent slope value.

19. The system of claim 5, further comprising determining a slope correction factor for each prominent slope value.

20. The system of claim 19, further comprising determining the area of the structure based on the area of the structure footprint, the prominent slope values, corresponding area percentages of the roof structure of the slope distribution report, and the slope correction factor for each prominent slope value.

21. A method for estimating at least one attribute of a structure, comprising:
receiving at a processor a point set stored in a memory;
selecting by the processor a plurality of roof structure points from said point set having a high probability of being positioned on a top surface of a structure;
determining by the processor a footprint of the structure associated with the plurality of roof structure points; and
determining by the processor at least one attribute of the structure based on the plurality of roof structure points.

22. The method of claim 21, wherein the at least one attribute comprises a slope of the structure.

23. The method of claim 22, further comprising determining by the processor a distribution of slopes of the roof structure points and generates a slope distribution report indicative of prominent slopes of the roof structure.

24. The method of claim 23, wherein the slope distribution report indicates a contribution by each slope toward the total roof structure.

25. The method of claim 23, further comprising determining by the processor an area of the structure based on the footprint of the structure and the slope distribution report.

26. The method of claim 21, further comprising selecting by the processor the plurality of roof structure points by partitioning a region of interest into two point sets based on whether the points have a high probability of being positioned on the top surface of the structure.

27. The method of claim 21, further comprising determining by the processor the footprint of the structure by determining a two-dimensional (2D) polygonal model indicative of the footprint of the structure in an XY plane corresponding to the point set.

28. The method of claim 21, further comprising refining by the processor the 2D polygonal model using at least one prior constraint.

29. The method of claim 23, further comprising determining by the processor the distributions of slopes of the roof structure points by:
determining a normal of each point of the roof structure point set;
orienting each normal for each point of the roof structure point set;
determining a slope of the structure at each roof structure point set utilizing each normal for each point of the roof structure point set;
removing outlier slopes; and
generating a histogram of slope values.

30. The method of claim 29, further comprising refining each normal for each point of the roof structure points utilizing a constraint or prior knowledge.

31. The method of claim 29, further comprising discretizing each slope.

32. The method of claim 29, further comprising determining peak values in the histogram and determining whether to utilize the peak values as respective representative slope values of each peak.

33. The method of claim 32, further comprising applying constraints to the histogram.

34. The method of claim 32, further comprising determining prominent slope values by determining a mean of the slopes that contributes to a peak histogram bucket.

35. The method of claim 32, further comprising determining a width of each peak value.

36. The method of claim 35, further comprising determining prominent slope values by selecting slope values that lie between a width left of a peak and the peak and between a width right of the peak and the peak.

37. The method of claim 32, further comprising removing slope values that do not contribute to any peak.

38. The method of claim 37, further comprising determining an area percentage of the roof structure for each prominent slope value.

39. The method of claim 25, further comprising determining a slope correction factor for each prominent slope value.

40. The method of claim 39, further comprising determining the area of the structure based on the area of the structure footprint, the prominent slope values, corresponding area percentages of the roof structure of the slope distribution report, and the slope correction factor for each prominent slope value.
